(19) United States
(12) Patent Application Publication
(10) Pub. No.: US 2016/0334664 A1
(43) Pub. Date: Nov. 17, 2016

(54) LIQUID CRYSTAL DISPLAY DEVICE WITH SUB-PIXEL ZONES FOR INDOOR AND OUTDOOR USE

(71) Applicant: Pebble Technology Corp., Palo Alto, CA (US)

(72) Inventor: Li Zhuang, Long Grove, IL (US)

(21) Appl. No.: 14/709,223

(22) Filed: May 11, 2015

(51) Int. Cl. G02F 1/1343; G02F 1/1362; H01L 27/12; G02F 1/133; G02F 1/1345; G02F 1/1368; G02F 1/1335

(52) U.S. Cl. CPC G02F 1/13439; G02F 1/1368; G02F 1/134336; G02F 1/13624; G02F 1/133514; G02F 1/13306; G02F 1/13454; H01L 27/124; G02F 2001/134345

(57) ABSTRACT

A LCD device with a pixel structure and a computing device with a display having the LCD device are disclosed. The LCD device includes a plurality of pixels for displaying visual content indoors and outdoors. The pixels in the LCD device include a transmissive sub-pixel zone with transmissive sub-pixels and a reflective sub-pixel zone with reflective sub-pixels. Each transmissive and reflective sub-pixel in the sub-pixel zones is connected to a MIP sub-pixel system and each sub-pixel zone may be individually controlled.

### BACKGROUND OF THE INVENTION

1. Field of the Invention

The invention relates generally to a liquid crystal display panel and an electronic apparatus including the same.

2. Description of the Related Art

User communication devices, such as smartphones and smartwatches, allow users to interact and communicate with users of other communication devices. Due to the characteristics of a thin profile and low power consumption, liquid crystal displays (LCDs) are widely used to display notifications and other information in these smartphones and smartwatches. Smartphone and smartwatch providers are constantly looking for an LCD display that can provide three performance characteristics—very good color/contrast, good outdoor readability, and very low power consumption (or always-on). However, current LCD displays compromise one performance characteristic for another.

Generally, LCD displays use LCD devices that are classified into transmissive, reflective, and transflective types. A transmissive LCD device uses a backlight light-emitting diode (LED) unit as its light source, and can display a bright image in a dark ambient environment. Transmissive LCD devices have good color/contrast but poor outdoor readability that may only be improved by boosting brightness of the LCD panels through use of a backlight unit. However, this transmissive LCD device consumes more power due to increased current used to drive the backlight unit. On the other hand, a reflective LCD device uses ambient light as its light source and so has an advantage of low power consumption since the reflective LCD does not include a backlight unit. However, a reflective LCD device has very poor indoor color and/or contrast. Further, the reflective LCD device cannot be used in a dark ambient environment unless front lighting is applied. A transflective LCD device makes use of both a backlight source and ambient light and, as such, provides good outdoor readability under sunlight as well as reasonable power consumption. However, a transflective LCD device has poor color/contrast during indoor use.

Thus, the need exists in the field of LCD displays for an LCD device that can provide good color/contrast during indoor use, good outdoor readability in daylight including direct sunlight, and which consumes low power.

### SUMMARY OF THE INVENTION

Implementations of the presently disclosed technology relate to an LCD device that includes a plurality of pixels for displaying visual content on an LCD during indoor and outdoor use. The pixels in the LCD device include a transmissive sub-pixel zone with transmissive sub-pixels and a reflective sub-pixel zone with reflective sub-pixels. The transmissive and reflective sub-pixels are formed on a substrate and support displaying colors and white or black in a plurality of operating modes. Each transmissive and reflective sub-pixel in the sub-pixel zones is connected to a memory-in-pixel (MIP) sub-pixel system and each sub-pixel zone may be individually controlled.

### BRIEF DESCRIPTION OF THE FIGURES

The accompanying drawings, which are incorporated in and constitute a part of this specification, illustrate an implementation of apparatuses and methods consistent with the present invention and, together with the detailed description, serve to explain advantages and principles consistent with the invention.

FIG. 1 is a block diagram that illustrates a configuration of a system using an LCD display device of the present invention.

FIGS. 2-3 illustrate a schematic diagram of a pixel structure of the LCD display device of FIG. 1, wherein the pixel structure includes transmissive and reflective sub-pixels according to an embodiment.

FIG. 4 illustrates a schematic cross-sectional view of the pixel structure of FIGS. 2-3 according to an embodiment.

FIG. 5A is a schematic view of a configuration of a MIP sub-pixel system that is used in the LCD display device of FIGS. 2-3 according to an embodiment.

FIG. 5B is a schematic diagram of a pixel structure of the LCD display device of FIG. 1 but is shown with a configuration of a MIP sub-pixel according to an embodiment.

FIG. 5C is a schematic diagram of a pixel structure of the LCD display device of FIG. 1 but is shown with a configuration of a MIP sub-pixel according to an embodiment.

FIGS. 6A-6B illustrate control of transmissive sub-pixels of an LCD display device using TFT switches according to an embodiment.

FIGS. 7A-7B illustrate control of reflective sub-pixels of an LCD display device using TFT switches according to an embodiment.

FIG. 8 illustrates a schematic diagram of a pixel structure of an LCD display device, wherein the pixel structure includes transmissive and reflective sub-pixels according to an embodiment.

FIG. 9 illustrates a schematic cross-sectional view of the pixel structure of FIG. 8 according to an embodiment.

FIGS. 10A-10G illustrate examples of computing devices that may be used with embodiments of the invention.

### DETAILED DESCRIPTION OF THE PREFERRED EMBODIMENTS

The present invention is directed to an improved LCD pixel structure having transmissive and reflective type sub-pixel zones and a LCD display device that incorporates the LCD pixel structure. The LCD display device is useful in electronics that incorporate an LCD display including LCD display devices in wearable computing devices such as, for example, smartwatches, smartphones and activity trackers, tablet, laptop/notebook, e-book reader, LCD monitor, TV monitor, digital cameras and other similar consumer electronics. An important feature of the disclosed pixel structure is a memory-in-pixel (MIP) system that drives sub-pixel electrodes that are connected to the reflective and transmissive type sub-pixel zones.

The following detailed description is merely illustrative in nature and is not intended to limit the embodiments of the subject matter or the application and uses of such embodiments. Any implementation described herein as exemplary is not necessarily to be construed as preferred or advantageous over other implementations.

For simplicity and clarity of illustration, the Figures depict the general methodology and/or manner of construction of the various embodiments. Descriptions and details of well-known features and techniques may be omitted to avoid unnecessarily obscuring other features.

Terms of enumeration such as “first,” “second,” “third,” and the like may be used for distinguishing between similar elements and not necessarily for describing a particular spatial or chronological order. These terms, so used, are interchangeable under appropriate circumstances.

The terms “comprise,” “include,” “have” and any variations thereof are used synonymously to denote non-exclusive inclusion. The term “exemplary” is used in the sense of “example,” rather than “ideal.”

In the interest of conciseness, conventional techniques, structures and principles known by those skilled in the art may not be described herein.

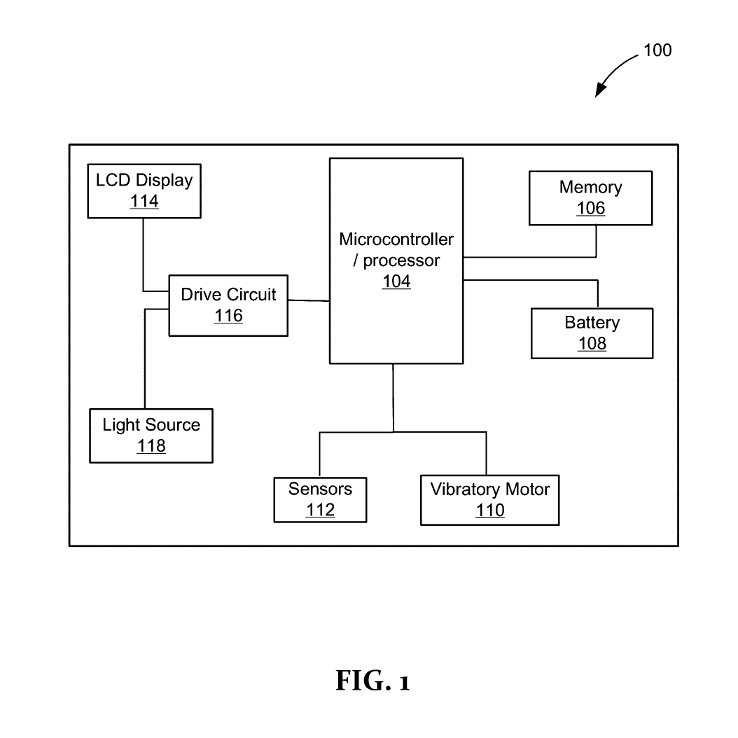

Turning now to the figures, FIG. 1 illustrates a system 100 that may be used with embodiments of the present invention. System 100 is applicable for use in wearable computing devices, for example, in smartwatches and activity trackers as well as for use in other electronic devices such as, for example, smartphones, tablets, laptop computers and other similar consumer electronics. For ease of illustration, the following description of system 100 is illustrated for use in a wearable computing device.

System 100 includes a microcontroller or processor 104, memory 106, battery 108, vibratory motor 110, sensors 112 (e.g., GPS, accelerometer, or other environmental sensor), display 114 (e.g., Liquid Crystal Display (“LCD”), such as twisted nematic (“TN”) LCD, electrically controlled birefringence (“ECB”) LCD, vertical alignment (“VA”) LCD or in-plane switching (“IPS”) LCD), drive circuit 116 and LED source 118. Battery 108 supplies electrical power to system 100. A vibratory motor 110 is connected to microcontroller 104 and can be activated by microcontroller 104 when a new message is received, which acts as notification to a user of the wearable computing device there is a new message. The drive circuit 116 may include driver circuits to independently drive thin film transistors the LCD display 114 for providing more vibrant color (for example, 262K or 16M color).

Memory 106 includes storage for operating system software and applications to be executed by microcontroller 104. Memory 106 stores information gathered by sensors 112 or other hardware associated with system 100. In an embodiment, memory 106 also includes algorithms for identifying environmental conditions that are executed by microcontroller or processor 104 in order to control how visual information is provided on display 114 in response to the environmental conditions, for example, when a user walks outdoors into sunlight from an indoor environment. It will be appreciated that the memory 106 discussed herein may include volatile and non-volatile, removable and non-removable media implemented in any method or technology for storage of information, such as computer readable instructions, data structures, program modules, or other data. Examples of computer storage media include RAM, ROM, EEPROM, flash memory or any other medium which can be used to store electronic information and which can be accessed by microcontroller or processor 104.

Sensors 112 may be configured to measure environmental conditions associated with the wearable computing device. For instance, sensors 112 may be configured to measure the position, location, rotation, velocity, acceleration, brightness and/or temperature of the wearable computing device. Examples of one of more of sensors 112 may include, but are not limited to, accelerometers, gyroscopes, temperature sensors, ambient light sensors or the like. Those of ordinary skill in the art will appreciate that other additional sensors could be used to provide information on environmental conditions around the wearable computing device.

LCD display 114 preferably includes a memory in pixel (“MIP”) system with pixels that may be associated with transmissive type LCD devices and reflective type LCD devices. The transmissive and reflective type LCD devices are each associated with the MIP system, which includes a memory that can store data in each pixel. The transmissive and reflective type LCD devices of the MIP system can support a monochrome display and a color display and may achieve a display in an analog display mode and in a memory display mode by having a memory for storing data within each pixel. In this case, the analog display mode is a display mode for displaying the gradation of the pixel in an analog manner. The memory display mode is a display mode for displaying the gradation of the pixel in a digital manner on the basis of binary information (logic “i”/logic “o”) stored in the memory within the pixel. An embedded 1-bit memory for every sub-pixel enables each sub-pixel to hold state while requiring very little current. In addition, there is a need to rewrite the display screen partially, that is, rewrite only a part of the display screen. In this case, it suffices to rewrite sub-pixel data partially. When the display screen is rewritten partially, that is, the sub-pixel data is rewritten partially, data does not need to be transferred to sub-pixels in which the rewriting is not performed. Therefore, an amount of data transfer can be reduced which improves the power saving of the LCD display 114. This delivers an “always on” display to LCD display 114 that uses little power. In embodiments, display modes of the transmissive type LCD devices may include a color mode and display modes of the reflective type LCD devices may include color and black and white mode.

Microcontroller or processor 104 is coupled to LCD display 114. Microcontroller or processor 104 is configured to supply various instructions and data to LCD display 114 in order to display visual information to a user on LCD display 114. Microcontroller 114 may display visual information in color mode or black and white mode in response to receiving sensor information from sensors 112 or an internal clock circuit. Microcontroller 104 is configured to execute instructions or algorithms that relate to receiving real-time display parameters that are inputted by a user or parameters that are detected with sensors 112 in the wearable computing device. For example, microcontroller 104 may be configured to receive instructions to turn ON color display mode so as to display color in addition to displaying black and white as when a user selects color mode in order to improve readability of the LCD display outdoors or indoors. Microcontroller 104 may also be configured to control LCD display to display information when a user moves from an indoor environment to outdoor environment. For example, ambient light sensors may be configured to detect sunlight indicating that the user is outdoors in the sun or GPS sensors may detect that a user has moved to an outdoor location that may cause the LCD display to display information in black and white mode in order to improve readability of the LCD display outdoors. Microcontroller 104 may also provide battery usage information to a user that notifies the user as to available battery life, or actual battery consumption when a user uses the several display modes on the wearable computing device.

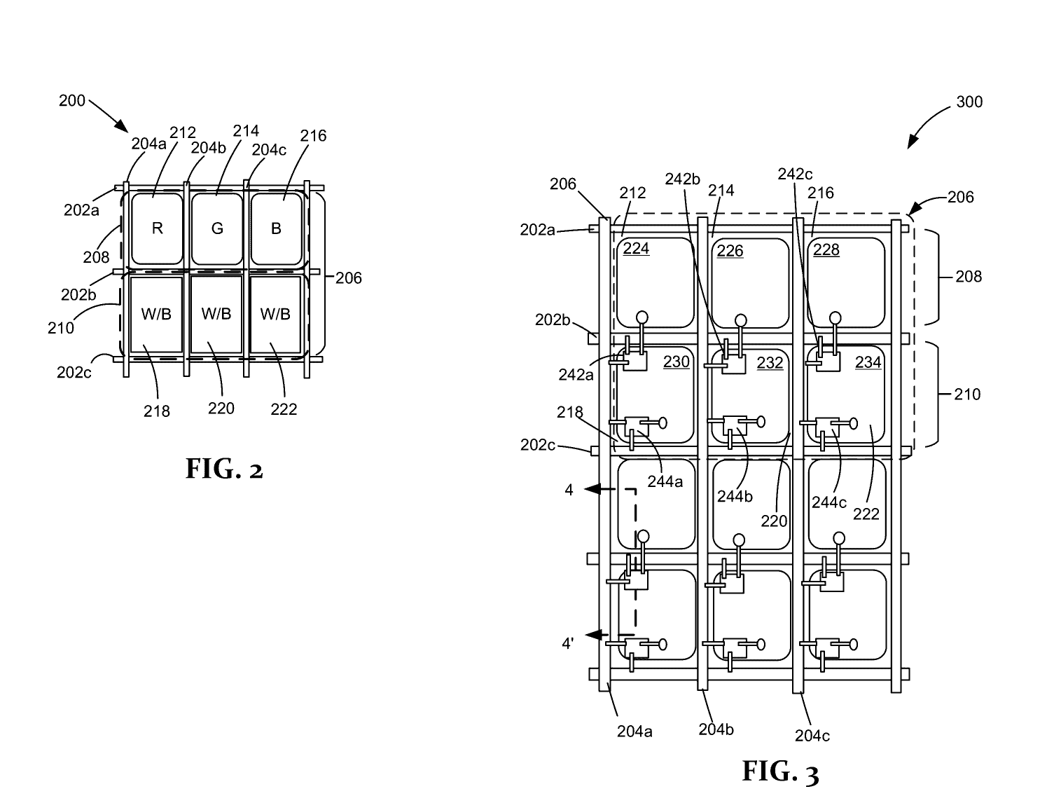

Turning now to FIG. 2, a schematic diagram of a MIP pixel structure 200 (“MIP Pixel 200”) is shown for use in LCD display 114 of FIG. 1 according to an embodiment. MIP Pixel 200 depicts a unit pixel region 206 that includes six sub-pixels with an embedded 1-bit memory for each sub-pixel. In other embodiments, each sub-pixel may include multiple-bit memory. In an embodiment, the number of sub-pixels can be an even number such as, for example, four, six or eight sub-pixels. In another embodiment, the number of sub-pixels may be an odd numbers such as, for example, three or five. However, other values of even or odd sub-pixels may be contemplated in unit pixel region 206 without departing from the scope of the invention.

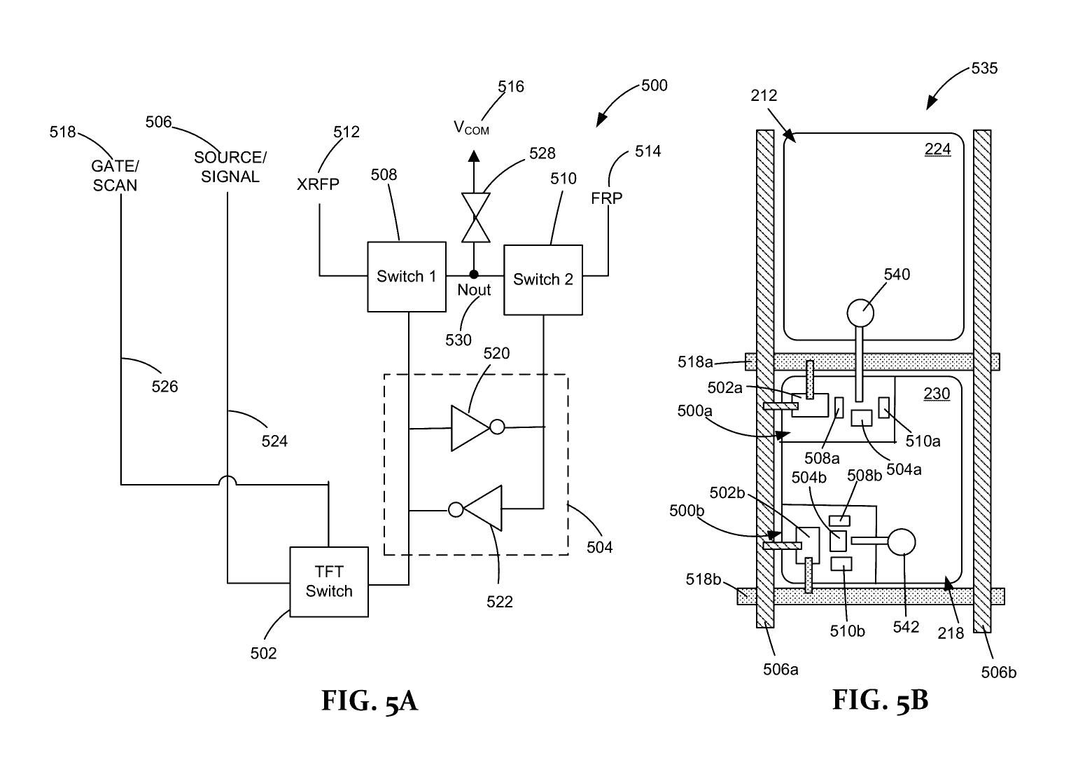

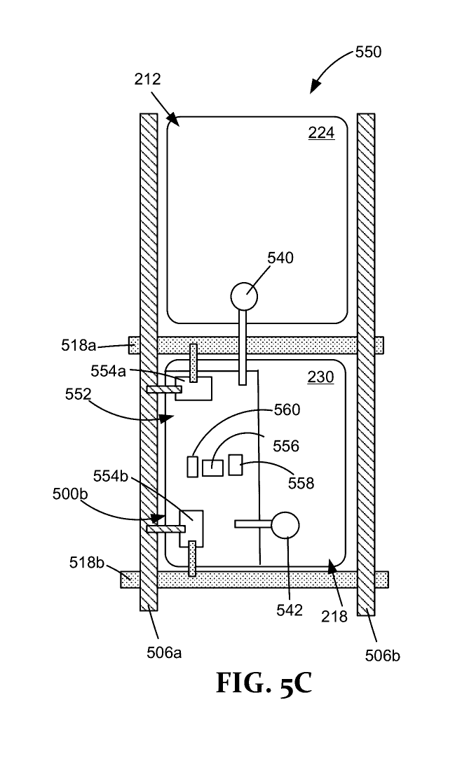

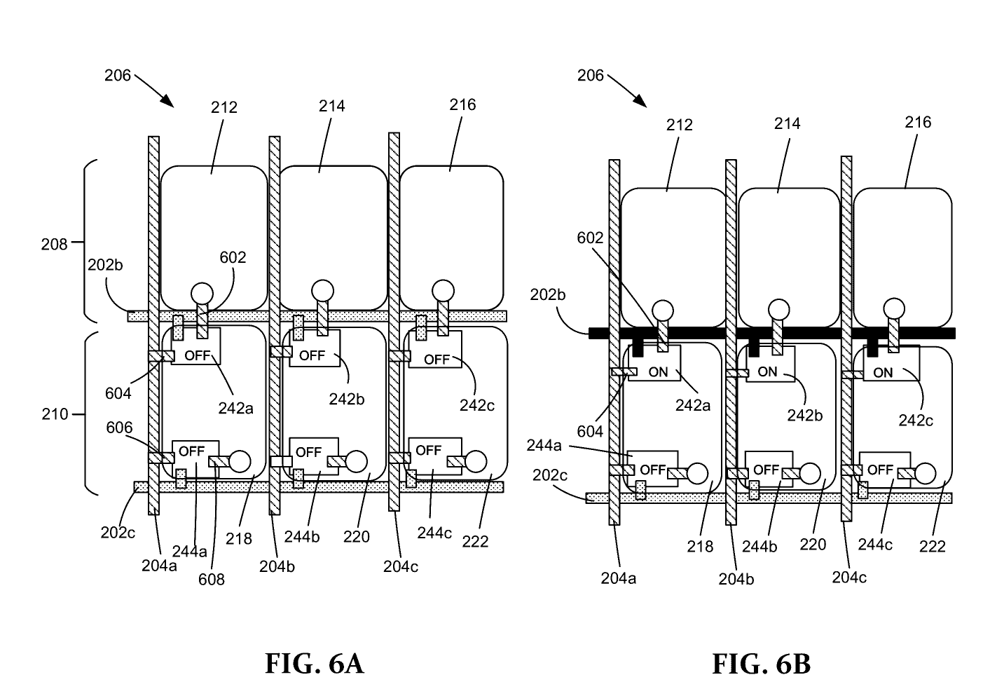

The sub-pixels are defined by gate or scan lines 202a-202c and source or signal lines 204a-204c. Particularly, unit pixel region 206 includes a plurality of substantially similar gate or scan lines 202a-202c disposed along a first direction on a substrate and a plurality of substantially similar source or signal lines 204a-204c disposed along a second direction on the substrate, which in an embodiment is a thin film transistor (“TFT”) glass substrate (hereinafter referred to as a “TFT substrate”). The unit pixel region 206 includes a plurality of sub-pixels 212, 214, 216, 218, 220 and 222. Further, each sub-pixel 212-222 in pixel region 206 is a MIP sub-pixel system which comprises a sub-pixel with a memory that can store data that may constantly apply a steady voltage to a pixel electrode in the corresponding sub-pixel. In embodiments, each sub-pixel zone 208, 210 may be driven by a MIP sub-pixel system and each sub-pixel zone 208, 210 may be individually controlled, as will be described below in reference to FIGS. 5-7B.

Sub-pixels 212, 214 and 216 collectively form a transmissive sub-pixel zone 208 with each sub-pixel 212, 214 and 216 being a transmissive sub-pixel. Sub-pixels 218, 220 and 222 collectively form a reflective sub-pixel zone 210 with each sub-pixel 218, 220 and 222 being a reflective sub-pixel. Each sub-pixel 212, 214 and 216 is a color sub-pixel that displays red, green or blue, or other colors including yellow, cyan, purple, grayscale or the like and each sub-pixel 218, 220 and 222 is a colorless sub-pixel that can display white or black. Transmissive sub-pixels 212, 214 and 216 may include, in embodiments, a color filter that may be used to display a corresponding plurality of colors including red, blue, green, yellow, cyan, purple or other colors. In embodiments, the reflective sub-pixels 218, 220 and 222 may be configured to display colors or white and black. The reflective sub-pixels that display black and white may be particularly useful in an outdoor mode in sunlight that can display visual information with high readability and low battery consumption, which may extend the battery life of the device, for example, a wearable computing device using the LCD display 114 (FIG. 1).

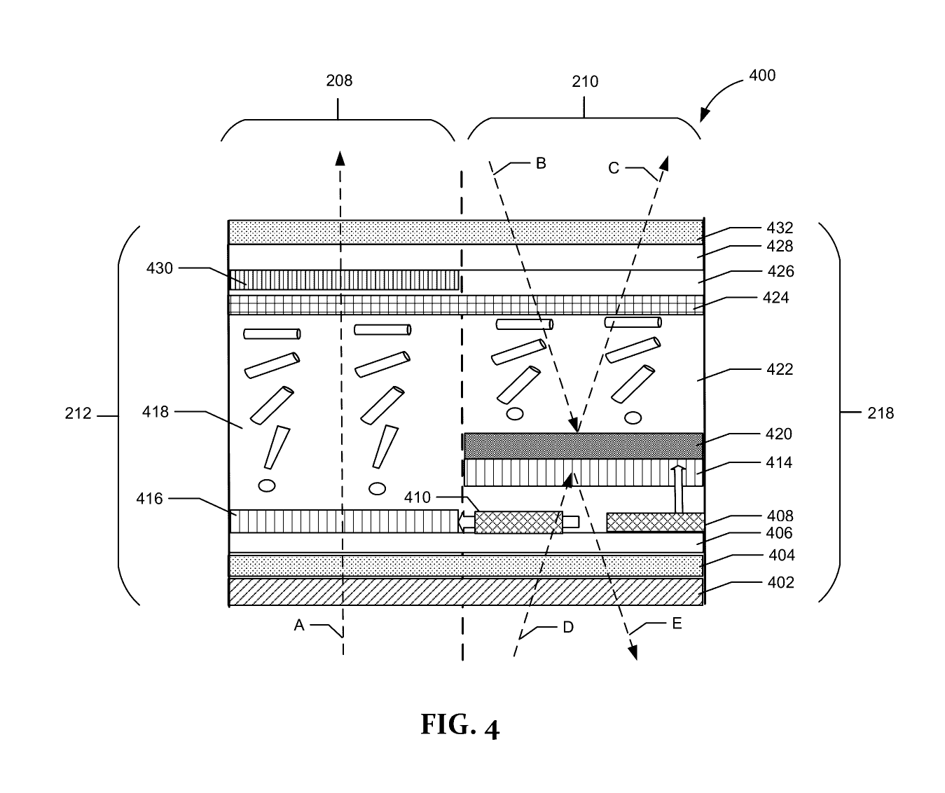

FIG. 3 illustrates a pixel structure for a MIP LCD device 300 of LCD display 114 (FIG. 1), which is formed by two-dimensionally arranging a plurality of unit pixel regions 206 of MIP pixel 200 in the form of a matrix according to an embodiment. Each pixel region 206 includes a transmissive sub-pixel zone 208 comprising transmissive sub-pixels 212, 214 and 216 that are arranged in a pixel row. Transmissive sub-pixels 212, 214 and 216 include respective transmissive pixel electrodes 224, 226 and 228. Pixel region 206 also includes a reflective sub-pixel zone 210 comprising reflective sub-pixels 218, 220 and 222 that are arranged in a pixel row immediately adjacent to the transmissive sub-pixels 212-216. The reflective sub-pixels 218, 220 and 222 include reflective pixel electrodes 230, 232 and 234. Also shown in FIG. 3, transmissive and reflective sub-pixel zones 208 and 210 include a MIP system with a 1-bit memory or with a multi-bit memory. In an embodiment, each transmissive and reflective sub-pixel 212-222 is a sub-pixel with an associated memory (“MIP sub-pixel”) having MIPs 242a, 242b, 242c, 244a, 244b and 244c that are formed on the TFT substrate (shown in FIG. 4). The MIPs 242a-242c and 244a-244c may allow each sub-pixel (for example, transmissive sub-pixels 212-216 or reflective sub-pixels 218-222) to hold its state and, thereby, reduce the driving current for LCD display 114 (FIG. 1). Each MIP sub-pixel includes a static random access memory (“SRAM”) function where sub-pixels have a latch section that can retain a voltage potential corresponding to display data, and which are arranged in the form of a matrix as is shown below with reference to FIG. 5. The MIPs 242a-242c and 244a-244c are disposed under the reflective pixel electrodes 230, 232, 234 in the reflective sub-pixel zone 210. While two MIP sub-pixels, for example, MIP sub-pixels 242a and 244a are depicted with MIP sub-pixel 242a being used with a transmissive sub-pixel and a MIP sub-pixel 244a being used with a reflective sub-pixel, in another embodiment, a single MIP sub-pixel may be used for controlling both the transmissive sub-pixel and the reflective sub-pixel, as is shown in FIG. 5C. In another embodiment, additional MIP sub-pixels are also contemplated for use with MIP LCD device 300 without departing from the scope of the invention. While a case of using a SRAM as a memory in the sub-pixel is taken as an example of a MIP in the present embodiment, a memory of another configuration such as, for example, a memory of a dynamic random access memory (“DRAM”) may also be used.

MIPs 242a-242c and 244a-244c include thin film transistors (TFTs) that are also formed on the TFT substrate and are used as switching devices for the transmissive and reflective sub-pixel zones 208 and 210. For example, transmissive sub-pixel zone 208 includes MIPs 242a-242c that are electrically connected to respective transmissive electrodes 224-228 and include TFTs that may be used to independently switch the transmissive sub-pixels 212, 214 and 216. Similarly, reflective sub-pixel zone 210 includes MIPs 244a-244c that are electrically connected to the respective reflective sub-pixels 218, 220 and 222 and include TFTs that may be used to independently switch the reflective sub-pixels 218-222. MIPs 242a-242c and 244a-244c are both located/disposed under the reflective pixel electrodes 230-234 in the reflective sub-pixel zone 210. Each sub-pixel in the transmissive sub-pixel zone 208 and an associated subpixel in reflective sub-pixel zone 210 is electrically connected to a MIP. For example, sub-pixel 212 is connected to MIP 242a and sub-pixel 218 is connected to MIP 244a; sub-pixel 214 is connected to MIP 242b and sub-pixel 220 is connected to MIP 244b; and sub-pixel 216 is connected to MIP 242c and sub-pixel 222 is connected to MIP 244c. Each respective MIP 242a-242c and 244a-244c cause their respective sub-pixels to hold their state so as to provide a display that is always “ON” thereby consuming low power during operation. In embodiments, the structure of the TFT in MIPs 242a-242c and 244a-244c may be bottom-gate type (such as back-channel etched, etching stopper or others) or top-gate type, and the implant types of TFTs may comprise N-type, P-type or combinations thereof. The fabrication process of the TFTs can include single silicon processes, microcrystalline silicon processes or combinations thereof.

Each transmissive sub-pixel 212-216 in the transmissive sub-pixel zone 208 and its corresponding reflective sub-pixel 218-222 in the same column (which is parallel to source lines 204a-204c) in the reflective sub-pixel zone 210 is connected to or share the same source line 204a-204c. For example, transmissive sub-pixel 212 and reflective sub-pixel 218 are connected to the same source line 204a through respective MIPs 242a and 244a, transmissive sub-pixel 214 and reflective sub-pixel 220 are connected to the same source line 204b through respective MIPs 242b and 244b and transmissive sub-pixel 216 and reflective sub-pixel 222 are connected to the same source line 204c through respective MIPs 242c and 244c. The source lines 204a-204c may selectively receive control signals to drive the respective sub-pixels for displaying visual information in color (e.g., R, G, B) or gray scale. Further, all transmissive sub-pixels 212-216 in the transmissive sub-pixel zone 208 are connected to the same gate line 202b through MIPs 242a-242c while all reflective sub-pixels 218-222 in a reflective sub-pixel zone 210 are connected to the same gate line 202c through MIPs 244a-244c. For example, transmissive sub-pixels 212, 214 and 216 are connected to the same gate line 202b and all reflective sub-pixels 218, 220 and 222 are connected to the same gate line 202C. The gate lines 202b-202c may selectively receive control signals to control the respective sub-pixels in order to turn ON or OFF the respective sub-pixel zones. In embodiments, the control signals may be PWM signals have varying duty cycles. Thus, each pixel row can be individually controlled and addressable by control signals that are provided on gate lines 202b-202c and source lines 204a-204c. In other embodiments, a driver circuit may be connected to the gate lines 202b-202c and source lines 204a-204c to drive the individual sub-pixels 212-222 in order to achieve multi-bit color depth, for example, to display 262K or 16M color.

Turning now to FIG. 4, a schematic view of pixel 400 for describing the pixel structure of pixel region 206 of LCD display 114 is shown according to an embodiment of the present invention. The schematic view of FIG. 4 is a simplified cross-section view of a transmissive type sub-pixel and a reflective type sub-pixel of LCD device 300 such as, for example, sub-pixels 212 and 218 of FIG. 3 across transmissive and reflective sub-pixel zones 208, 210. Pixel 400 may not necessarily depict a planar structure for certain layers such as, for example, TFTs and MIPs. While FIG. 4 depicts transmissive and reflective type sub-pixels 212 and 218, it is to be appreciated that structure of transmissive sub-pixels 214-216 and reflective sub-pixels 220-222 in LCD device 300 are substantially similar to the transmissive and reflective type sub-pixels 212 and 218 of LCD 300.

Pixel 400 includes a transmissive sub-pixel zone 208 and a reflective sub-pixel zone 210. Although not shown, a plurality of scan lines are disposed along a first direction on a substrate and a plurality of signal lines disposed along a second direction on the substrate that separate a pair of transmissive and reflective sub-pixel zones 208, 210 from another pair of transmissive and reflective sub-pixel zone of the pixel region 206. The transmissive and reflective sub-pixel zones 208, 210 include a backlight unit 402, a rear polarizing plate 404 and a TFT glass substrate 406. The backlight unit 402, polarizer (or polarizing plate) 404 and TFT glass substrate 406 extend across the transmissive and reflective sub-pixel zones 208 and 210. The backlight unit 402 can be the light source 118 of FIG. 1. Circuit elements including switching elements, memory elements and capacitive elements, such as MIPs 408 and 410 that are formed on the TFT glass substrate 406 for controlling the transmissive and reflective sub-pixels 212 and 218. The MIPs 408, 410 may be co-planarly disposed on the TFT glass substrate 406 but are shown in FIG. 4 as stacked features for simplicity. The MIPs 408, 410 are disposed on the TFT glass substrate 406 and under a part of a reflective pixel electrode 414 in the reflective sub-pixel zone 210. Transmissive sub-pixel 212 further includes a transmissive pixel electrode 416 and a liquid crystal layer 418. Transmissive pixel electrode 416 may be formed of an indium tin oxide (ITO) and is transparent in order to allow light emanating from backlight unit 402 to pass through transmissive pixel electrode 416 in the direction of arrow A. Reflective sub-pixel 218 includes the reflective pixel electrode 414, a reflective layer 420 and a liquid crystal layer 422 coextensive with reflective sub-pixel zone 210. Light emanating from backlight unit 402 in the direction of arrow D is reflected off reflective layer 420 and back to backlight unit 402 in the direction of arrow E. A transparent common electrode 424 extends across transmissive sub-pixel zone 208 and reflective sub-pixel zone 210. Transparent common electrode 424 is directly opposite each liquid crystal layer 418 and 422 of the respective transmissive sub-pixel 212 and the reflective sub-pixel 218. The reflective pixel electrode 414 drives the liquid crystal layer 422 with the potential difference between the reflective electrode 414 and the common electrode 424 while the transmissive pixel electrode 416 drives the liquid crystal layer 418 with the potential difference between the transmissive pixel electrode 416 and the common electrode 424.

Transmissive sub-pixel 212 may include a color filter 430 that only extends across transmissive sub-pixel zone 208 for a portion of common electrode 424 and is coated on a color filter (CF) glass substrate 428 that is coextensive with the transmissive sub-pixel zone 208. Also, reflective sub-pixel 218 may not include a color filter in location 426 for a portion of common electrode 424 that is coextensive with the reflective sub-pixel zone 208. The upper surface of the CF glass substrate 428 includes a front polarizer 432 that extends across the transmissive and reflective sub-pixel zones 208 and 210. Front polarizer 432 serves as a display surface for the sub-pixels. Incident light from backlight unit 402 that travels through color filter 430 is displayed as either red, green, blue, cyan, yellow, purple or other colors based on the particular type of color filter that is used. Also, ambient light may be used for the reflective sub-pixel 218. Ambient light from sunlight can be used as a light source and is incident on reflective sub-pixel 218 in the direction of arrow B. Ambient light travels through liquid crystal layer 422 to be reflected back to a viewer along direction of arrow C for display as white or black colors. Since reflective sub-pixel 218 does not include a color filter in the reflective sub-pixel zone 210 and, thus, reflective sub-pixel 218 may display white or black in a colorless operation mode.

Using the sub-pixel configuration depicted in FIG. 4, LCD display 114 (FIG. 1) that utilizes pixel 400 may improve on previous displays currently in use, For example, pixel 400 may provide good outdoor readability, very low power consumption, and very good color/contrast indoors and outdoors in a plurality of operational modes, For example, the transmissive sub-pixel 212 may be configured to display 8 colors or 64 colors indoors or outdoors with the MIP 410 driving the transmissive electrode 416 and the backlight unit 402 ON or to display vibrant 262K or 16M color indoors or outdoors with an external display driver driving the transmissive electrode 416 with the backlight unit 402 ON, as will be described below. Further, the reflective subpixel 218 may use ambient light to display black or white outdoors or indoors under lighted conditions in a display mode.

FIGS. 5A and 5B depict operation of MIP sub-pixels in LCD display according to an embodiment. FIG. 5A depicts a schematic view of a configuration of a sub-pixel with memory 500 (MIP sub-pixel 500) that is used in LCD display 114 (FIG. 1) according to an embodiment of the invention. Particularly, the MIP sub-pixel 500 may be used for the transmissive sub-pixels 212-216 and reflective sub-pixels 218-222 in the transmissive and reflective sub-pixel zones 208 and 210, respectively for achieving a display in the analog display mode and in the memory display mode.

As shown in FIG. 5A, MIP sub-pixel 500 has a sub-pixel configuration provided with a SRAM function and includes three switch elements 502, 508 and 510, a latch section 504 and a liquid crystal cell 528. The liquid crystal cell 528 in this case represents a liquid crystal capacitance occurring between pixel electrode and a counter electrode 516 disposed so as to be opposite to the pixel electrode. Switch element 502 may be a TFT switch and can be formed by an N-channel MOS (or FET) transistor, for example. Switch element 502 has a source/drain connected to a source or signal line 506 and has a gate connected to a gate or scan line 518. A data signal 524 from source line 506 can be received by TFT switch 502. A gate signal 526 from gate line 518 can be selectively controlled to set values on the latch section 504. For example, the gate line 518 may be controlled to turn ON or turn OFF the switch element 502 when the switch element 502 is set in an ON (closed) state, the switch element 502 takes in a data signal 524 supplied via a source line 506.

The latch section 504, the memory element in the sub-pixel, is formed by inverters 520 and 522 that are connected in parallel with each other and in opposite orientations from each other. The latch section 504 retains (latches) a potential corresponding to the data signal 524 taken in by the switch element 502. Switch elements 508 and 510 may be transfer switches that are formed by connecting TFT transistors in parallel with each other, for example. Alternatively, switch elements 508 and 510 may be formed by using TFTs of a single conductivity, for example, an N-channel field effect transistor (“FET”) or a P-channel FET. The common connection node of the switch elements 508 and 510 is the output node Nout 530 of the MIP sub-pixel 500. One of the switch elements 508 and 510 may be set in an ON state according to the polarity of the potential retained by the latch section 504. The switch elements 508 and 510 supply a control pulse FRP 512 in phase with a common potential V_{COM} 516 applied the counter electrode of the liquid crystal cell 528 or a control pulse XRFP 512 in opposite phase from the common potential V_{COM} 516 to the sub-pixel electrode of the liquid crystal cell 528. Nout 530 is a common node connected switch element 508 and switch element 510. In operation, when the potential retained by the latch section 504 has a negative side polarity, the pixel potential of the liquid crystal cell 528 is in phase with the common potential V_{COM} 516 and thus the sub-pixel is switched OFF (for example, black is displayed for sub-pixels 212 or 218 in FIG. 3). When the polarity retained by the latch section 504 has a positive polarity, the pixel potential of the liquid crystal cell 528 is in opposite phase from the common potential V_{COM} 516 and thus the sub-pixel is turned ON (for example, color is displayed for sub-pixel 212 or white is displayed for sub-pixel 218).

As shown in FIG. 5B, a sub-pixel structure 535 includes MIP 500a that is associated with the transmissive sub-pixel 212 and MIP 500b that is associated with the reflective sub-pixel 218 according to an embodiment. MIP 500a includes TFT switch 502a, latch section 504a, and transfer switches 508a and 510a. Switch element 502a has a source/drain connected to a source line 506a and has a gate connected to a scan line 518a. A gate signal 526 (see FIG. 5A) on gate line 518a can be selectively controlled to set values on the latch section 504a. For example, the gate line 518b may be controlled to turn ON or turn OFF the switch element 502a when the switch element 502a is set in an ON (closed) state, the switch element 502a takes in a data signal 524 (see FIG. 5A) supplied via a source line 506a. Transfer switches 508a and 510a may be selectively controlled to drive transmissive pixel electrode 224 via a signal on line 540. Similarly, MIP 500b is associated with reflective sub-pixel 218 and includes TFT switch 502b, latch section 504b, and transfer switches 508b and 510b. Switch element 502b has a source/drain connected to a source line 506a and has a gate connected to a scan line 518b. A gate signal 526 (see FIG. 5A) on gate line 518b can be selectively controlled to set values on the latch section 504b. For example, the gate line 518b may be controlled to turn ON or turn OFF the switch element 502b when the switch element 502b is set in an ON (closed) state, the switch element 502b takes in a data signal 524 (see FIG. 5A) supplied via a source line 506a. Transfer switches 508b and 510b may be selectively controlled to drive reflective pixel electrode 230 via a signal on line 542.

As shown in FIG. 5C, a sub-pixel structure 550 includes MIP 552 that is associated with both the transmissive sub-pixel 212 and the reflective sub-pixel 218 according to an embodiment. MIP 552 includes TFT switches 554a and 554b, latch section 556, and transfer switches 558 and 560. Switch elements 554a and 554b are substantially similar to switch element 502 (FIG. 5A), latch section 556 may be latch section 504 (FIG. 5A) and transfer switches 558, 560 may be respective transfer switches 508, 510 (FIG. 5A). Switch element 554a has a source/drain connected to a source line 506a and has a gate connected to a scan line 518a. A gate signal 526 (see FIG. 5A) on gate line 518a can be selectively controlled to set values on the latch section 556. For example, the gate line 518b may be controlled to turn ON or turn OFF the switch element 554a when the switch element 554a is set in an ON (closed) state, the switch element 554a takes in a data signal 524 (see FIG. 5A) supplied via a source line 506a. Transfer switches 558 and 560 may be selectively controlled to drive transmissive pixel electrode 224 via a signal on line 540. Switch element 554b has a source/drain connected to a source line 506a and has a gate connected to a scan line 518b. A gate signal 526 (see FIG. 5A) on gate line 518b can be selectively controlled to set values on the latch section 556. For example, the gate line 518b may be controlled to turn ON or turn OFF the switch element 554b when the switch element 554b is set in an ON (closed) state, the switch element 554b takes in a data signal 524 (see FIG. 5A) supplied via a source line 506a. Transfer switches 558 and 560 may be selectively controlled to drive reflective pixel electrode 230 via a signal on line 542.

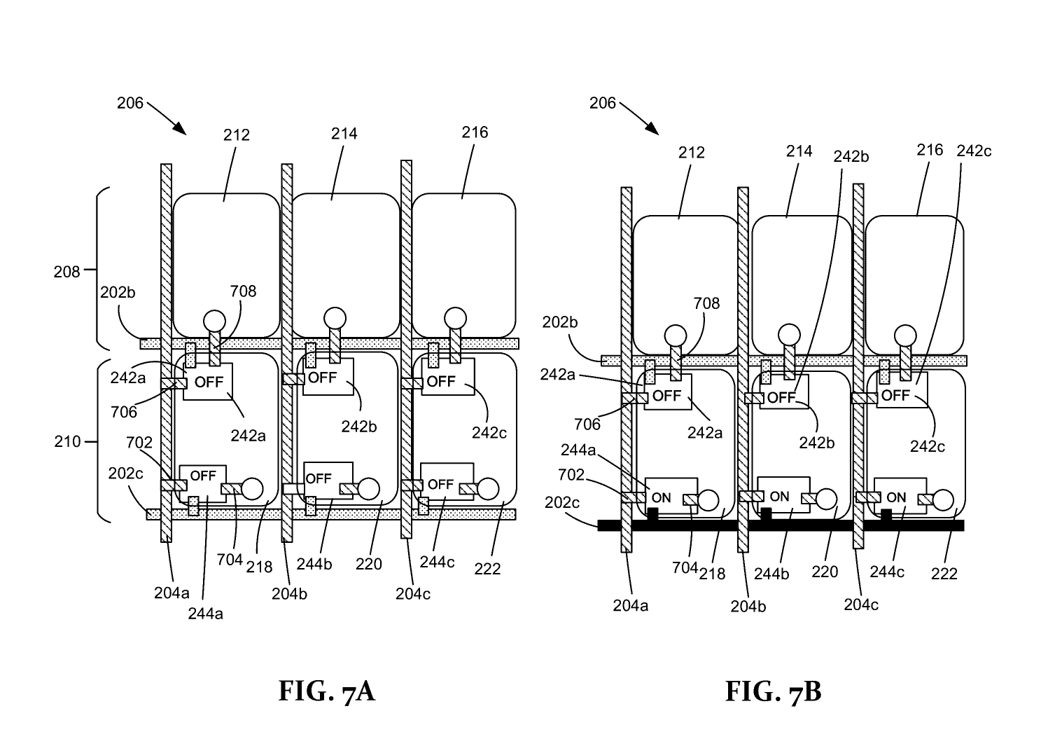

FIGS. 6A-6B illustrate a control scheme to control operation of the transmissive and reflective sub-pixels 212-216 and 218-222, respectively, of a MIP pixel, for example MIP pixel 300 of FIG. 3 using MIPs 242a-242c and 244a-244c according to an embodiment. Particularly, FIGS. 6A-6B depict a control scheme for turning ON the transmissive sub-pixels 212-216 while keeping the reflective sub-pixels 218-222 turned OFF. In FIGS. 6A-6B, parts corresponding to those of FIG. 3 are identified by the same reference numerals. In one embodiment, the source lines 204a-204c may selectively receive signals from a microcontroller 104 (FIG. 1) for controlling the transmissive and reflective sub-pixels. Also, the gate lines 202b-202c may be selectively controlled by receiving signals from microcontroller 104 to set latch values in the MIPs so as to turn ON or OFF the MIPs in the transmissive sub-pixel zone 208 and the reflective sub-pixel zone 210. In an embodiment, the gate and source lines 202b-202c and 204a-204c, respectively, may be driven by a driver IC in order to drive the MIPs in a multi-bit mode and achieve higher color depth.

Initially, as shown in FIG. 6A, MIPs 242a-242c and 244a-244c are OFF. In an embodiment, and with particular reference to transmissive sub-pixel 212 and reflective sub-pixel 218, the MIPs 242a-242c and 244a-244c are OFF where the source 604 is disconnected from the drain 602 of a TFT 502a (FIG. 5B) (that is, there is no drain-to-source current) and the source 606 being disconnected from the drain 608 of a TFT 502b (FIG. 5B). As the source lines 204a-204c can be loaded with a source voltage with no voltage signal being provided on gate lines 202b-202c, the gate voltage on TFT switches in respective MIPs 242a and 244a such as, for example, TFTs 502a and 502b (FIG. 5B) are below the respective source voltages which pinches the channel (or connection) between the respective sources 604, 606 and drains 602, 608 in order to turn OFF the TFT switches 502a and 502b (FIG. 5B). The MIPs 242a and 242b may retain a potential on the transmissive sub-pixels 212-216 and reflective sub-pixels 218-222 independently from a previous latch state. As shown in FIG. 6B, when a gate signal is applied to gate line 202b, a latch value is set on the latch section of the MIP 242a-242c. For example, a gate signal on gate line 202b can be selectively controlled to turn ON or turn OFF the switch element 502a (FIG. 5B). When the switch element 502a is set in an ON (closed) state, the switch element 502a takes in a data signal 524 (see FIG. 5A) supplied via a source line 204a and set a latch value on the latch section 504a (FIG. 5B) of MIP 242a-242c. The transfer switches 508a and 510a (FIG. 5B) may be controlled to transfer the latch value to the respective sub-pixel electrodes of the transmissive sub-pixels 212-216 thereby turning ON the transmissive sub-pixels 212-216.

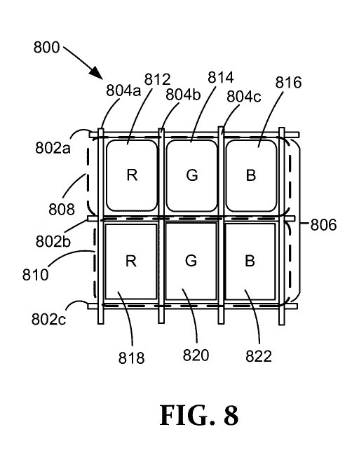

FIGS. 7A-7B illustrate a control scheme to control operation of the transmissive and reflective sub-pixels 212-216 and 218-222, respectively, of a MIP pixel, for example MIP pixel 300 of FIG. 3 using MIPs 242a-242c and 244a-244c according to an embodiment. Particularly, FIGS. 6A-6B depict a control scheme for turning ON the reflective sub-pixels 218-222 while keeping the transmissive sub-pixels 216-218 turned OFF. In FIGS. 6A-6B, parts corresponding to those of FIG. 3 are identified by the same reference numerals. Initially, as shown in FIG. 6A, MIPs 242a-242c and 244a-244c are OFF. In an embodiment, and with particular reference to transmissive sub-pixel 212 and reflective sub-pixel 218, the MIPs 242a-242c and 244a-244c are OFF with the source 706 being disconnected from the drain 708 of a TFT switch 502a (FIG. 5B) and the source 702 being disconnected from the drain 704 of TFT switch 502b (FIG. 5B). The MIPs 242a and 242b may retain from a previous latch state a potential on the transmissive sub-pixels 212-216 and reflective sub-pixels 218-222 independently. As shown in FIG. 7B, when a gate signal is applied to gate line 202c, a latch value is set on the latch section of the MIP 244a-244c. For example, a gate signal on gate line 202C can be selectively controlled to turn ON or turn OFF the switch element 502b (FIG. 5B). When the switch element 502b is set in an ON (closed) state, the switch element 502b takes in a data signal 524 (see FIG. 5A) supplied via a source line 204a and sets a latch value on the latch section 504b (FIG. 5B) of MIP 244a-244c. Further, the transfer switches 508b and 510b (FIG. 5B) may be controlled to transfer the latch value to the respective sub-pixel electrodes of the reflective sub-pixels 218-222 thereby turning ON the reflective sub-pixels 218-222.

Referring to FIGS. 2-7B, the LCD display 114 (FIG. 1) may be selectively controlled by the microcontroller or processor 104 to display visual information in color, gray scale and black or white in a plurality of display modes that is always ON. Particularly, the transmissive sub-pixel zone 208 and the reflective sub-pixel zone 210 of a pixel region 206 may be selectively driven in order to display visual information to a user, for example, of a wearable computing device having the LCD display 114. In embodiments, a plurality of display modes may be selected by the microcontroller 104 based on algorithms that are stored in memory 106 that are executed by microcontroller 104 in response to receiving sensor information from sensors 112 (FIG. 1) that indicates the ambient conditions around the wearable computing device. Additionally, a plurality of display modes may be displayed by a user selecting buttons on the wearable computing device which correspond to pre-configured algorithms that are stored in memory 106 and that are executed by microcontroller 104. For example, one or more display modes may be executed by microcontroller 104 based on user selection of a display mode while interacting in real-time with the wearable computing device having the LCD display 114 (FIG. 1). Additionally, in an embodiment, a first user display mode may be concurrently presented with a second user display mode, whereby the first mode may transition off after a predetermined period or upon sensing ambient conditions around the wearable computing device such as, for example, a user selects color mode outdoors in bright sunlight when black/white is also displayed. The color mode may transition off after a predetermined period based on a modulation scheme stored in memory 106. The following are examples of display modes that may be provided on LCD display 114 (FIG. 1) to a user of the wearable computing device: 1) black and white MIP mode, 2) transmissive color MIP mode (8 color or 64 color), 3) hybrid transflective MIP mode (8 color or 64 color), 4) high color depth transmissive mode (262K or 16M color) and 5) hybrid transflective high color depth mode (262K or 16M color).

1) Black and White MIP Mode:

The LCD display 114 may be configured to display visual information to a user using the black and white MIP mode outdoors in daylight including sunlight and display it indoors in well-lit conditions. In the black and white MIP mode, the reflective sub-pixels may be turned ON with the MIP driving the reflective sub-pixels and the transmissive sub-pixels may be turned OFF. The black and white MIP mode is used to display visual information in black and white without use of a backlight source and where a light source, for example, sunlight or indoor light is available to provide reflectivity. As such, the black and white MIP mode is a reflective black and white display mode that improves on outdoor readability of the prior art by using the reflective MIP to drive the reflective sub-pixels so as to provide good outdoor readability in daylight including sunlight, good indoor readability under lighted conditions and consume very low power.

2) Transmissive Color MIP Mode (8 Color or 64 Color):

The LCD display 114 may be configured to display visual information to a user in 8 colors, for example, i-bit on each red, green and blue sub-pixel or 64 colors, using the transmissive color MIP mode. In the transmissive color MIP mode, the transmissive sub-pixels are turned ON with the MIPs driving the transmissive sub-pixel electrodes with the backlight unit being used as a light source and the reflective sub-pixels are turned OFF. The LCD display 114 may use the transmissive color MIP mode in indoor environments and in darker conditions for displaying color and black or white to a user using the transmissive sub-pixels. In this mode, the LCD display 114 may be used to display color information indoors in dim light, used to display color information indoors under normal lighted conditions or used to display color information outdoors in bright sunlight. Displaying visual information outdoors in sunlight may be selected by a user to boost reading color information that is displayed on the LCD display 114. As such, the transmissive color MIP mode improves on the prior art by using a backlight unit with the transmissive MIP to provide vibrant colors and/or contrast indoors under dark or normal lighted conditions with very low power consumption.

3) Hybrid Transflective MIP Mode (8 Color or 64 Color):

The LCD display 114 may be configured to display color information to a user in 8 colors, for example, i-bit on each red, green and blue sub-pixel or 64 color, using the hybrid transflective MIP mode that is determined by the microcontroller or processor 104. In the hybrid transflective MIP mode, the transmissive sub-pixels are turned ON with the backlight unit used as a light source and the reflective sub-pixels are also turned ON. The transmissive and reflective MIPs drive both of their respective transmissive and reflective sub-pixel electrodes at the same time to provide 8 colors (or 64 color) as well as black and white both indoors and outdoors. The LCD display 114 may use the hybrid transflective MIP mode in dim outdoor environments and in dim indoor conditions to display visual information in color and black or white to a user. As such, the hybrid transflective MIP mode improves on the prior art by using a backlight unit with the transmissive MIP to provide-good colors indoors and muted colors outdoors under dark or dim-lighted conditions with very low power consumption.

4) High Color Depth Transmissive Mode:

The LCD display 114 may be configured to display color information with higher color depth, for example, a 262K color mode or a 16M color mode using the high color depth transmissive mode. In the high color depth transmissive mode, the transmissive sub-pixels are turned ON and the reflective sub-pixels are turned OFF. The backlight unit is used as a light source and a driver IC circuit drives the transmissive sub-pixel electrodes without using the transmissive MIPs (MIPs turned OFF). The LCD display 114 may use the high color depth transmissive mode in indoor environments and outdoors for displaying visual information generally in vibrant color (with a higher color depth) to a user. In this mode, the LCD display 114 may be used to display visual information indoors in dim light, used to display visual information indoors under normal lighted conditions or used to display visual information outdoors in order to boost reading color information that is displayed on the LCD display 114. As such, the high color depth transmissive mode provide a display with very good colors and high contrast for indoor environments or darker environments.

5) Hybrid Transflective High Color Depth Mode:

The LCD display 114 may be configured to display visual information in color with higher color depth such as, for example, a 262K color mode or a 16M color mode and in gray scale using the hybrid transflective high color depth mode. The LCD display 114 may use the hybrid transflective high color depth mode in selective indoor and outdoor environments where there is not enough light for displaying visual information to a user. In this mode, the LCD display 114 may be used to display visual information indoors under dim-lighted conditions or used to display visual information outdoors under dim-lighted conditions. In the hybrid transflective high color depth mode, both the transmissive sub-pixels and the reflective sub-pixels are turned ON with one or more driver IC circuits driving the transmissive and reflective sub-pixels with the MIPs turned OFF. The backlight unit is used as a light source. Using the IC driver for the reflective sub-pixels may also provide gray scale color. The hybrid transflective high color depth mode is using both the black and white and color modes at the same time, which may be use in transition conditions where light conditions preclude driving only the transmissive sub-pixels or only the reflective sub-pixels alone.

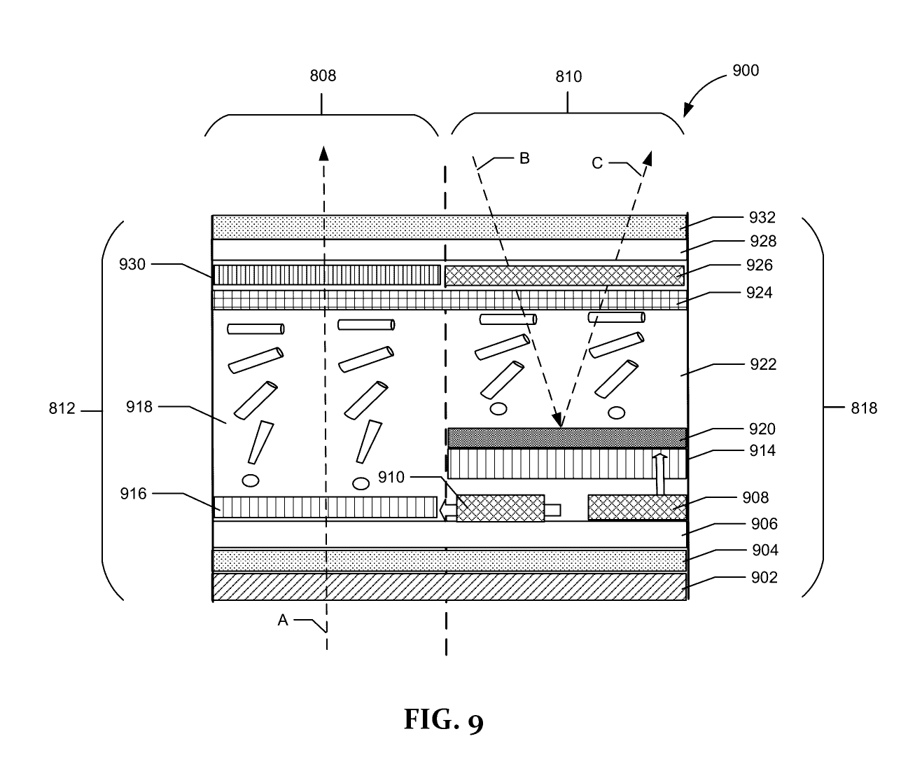

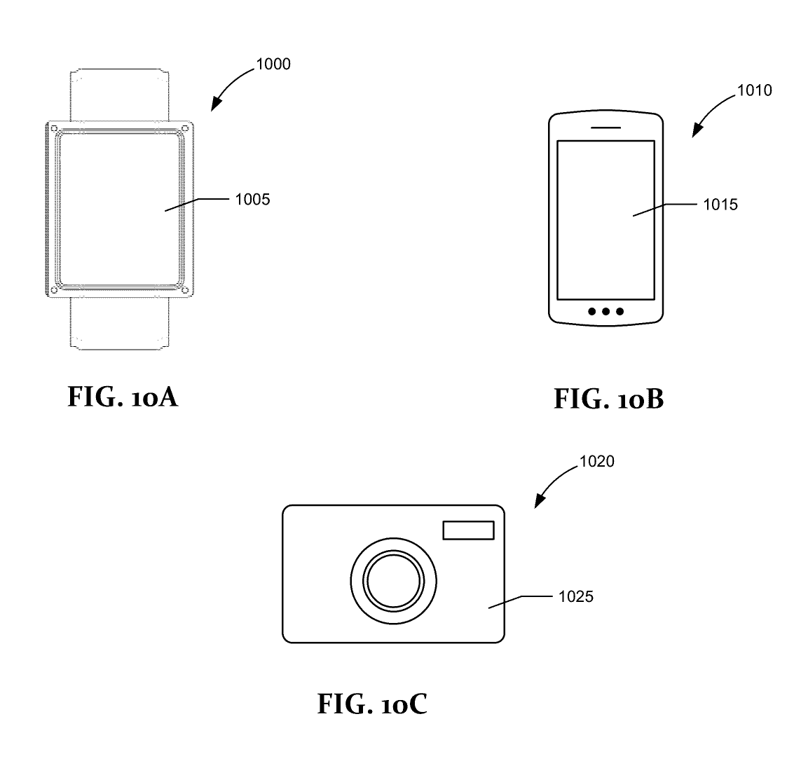

In another embodiment, FIG. 8 depicts a schematic diagram of a MIP pixel structure 800 (“MIP pixel 800”) having pixel region 806 that is configured for use in an LCD display. MIP pixel 800 is substantially similar to MIP pixel 200 of FIG. 2 except that the transmissive sub-pixel zone 808 and the reflective sub-pixel zone 810 both include color filters while all other aspects of FIG. 2 remain the same in FIG. 8, as will be shown below with reference to FIG. 9.

As shown in FIG. 8, MIP pixel 800 depicts a unit pixel region 806 that includes a plurality of substantially similar gate or scan lines 802a-802c and a plurality of substantially similar source or signal lines 804a-804c disposed along a second direction. Each unit pixel region 806 includes a plurality of sub-pixels 812, 814, 816, 818, 818, 820 and 822. Each sub-pixel 812-822 is a color sub-pixel comprising red, green and blue, or other colors including yellow, cyan, purple, grayscale or the like. Sub-pixels 812, 814 and 816 collectively form a transmissive sub-pixel zone 808 with each sub-pixel 812, 814 and 816 being a transmissive sub-pixel while sub-pixels 818, 820 and 822 collectively form a reflective sub-pixel zone 810 with each sub-pixel 818, 820 and 822 being a reflective sub-pixel. The Transmissive and reflective sub-pixels 812-822 include color filters that are used to display a corresponding red, blue, green, yellow, cyan, purple or other colors such as gray scale, as will be described below in reference to FIG. 9. Further, each sub-pixel 812-822 in pixel region 806 is a MIP sub-pixel system, as was described earlier in reference to FIGS. 5-7B.

Turning now to FIG. 9, a schematic view of pixel 900 that is used for explaining the pixel structure of pixel region 806 (FIG. 8) of LCD display 114 according to an embodiment is shown. The pixel 900 is substantially similar to pixel 400 of FIG. 4, except that a color filter 930 extends across the transmissive sub-pixel 812 and a color filter 926 extends across the reflective sub-pixel 818. The schematic view of FIG. 9 is a simplified cross-section view of a transmissive type sub-pixel and a reflective type sub-pixel of pixel 900 such as, for example, sub-pixels 812 and 818 of FIG. 8 across transmissive and reflective sub-pixel zones 808, 810. While FIG. 9 depicts unit transmissive and reflective type sub-pixels, it is to be appreciated that the schematic view of MIP pixel 900 is substantially similar to the other transmissive and reflective type sub-pixels of MIP pixel 800.

The structure of pixel 900 is substantially similar to structure of pixel 400 of FIG. 4 except that the transmissive sub-pixel zone 808 includes a color filter 930 and the reflective sub-pixel zone 810 includes a color filter 926. The color filter 930, in one embodiment, may have a high color gamut and the color filter 926 may have a lower color gamut. The advantage of the color filter 926 provides good reflective color particularly in outdoor environments. This improves upon prior art transflective LCDs, which usually do not have a color filter covering the reflective pixel region and, therefore, the color may be washed out in outdoor environments.

Pixel 900 includes a backlight unit 902, a rear polarizing plate 904, a TFT glass substrate 906, MIPs 908, 910, a reflective pixel electrode 914, a transmissive pixel electrode 916, a reflective layer 920, liquid crystal layers 918, 922, a transparent common electrode 924, and a front polarizer 932. The color filters 926 and 930 are coated on the color filter (CF) glass substrate 928 that is coextensive with the transmissive and reflective sub-pixel zones 808, 810. In operation, incident light from backlight unit 902 along a direction of arrow A that travels through color filter 930 is displayed as vibrant colors in either red, green, blue, cyan, yellow, purple or other colors based on the particular type of color filter that is used. As reflective sub-pixel 818 also includes a color filter 926, thus, reflective sub-pixel 818 may also display muted colors in red, green, blue, cyan, yellow, purple or other colors in a color mode based on incident light in direction of arrow B that is reflected back to a use through color filter 926 in the direction of arrow C.

Referring to FIGS. 1 and 8-9, an LCD display 114 (FIG. 1) that includes MIP pixel 800 that may be selectively controlled by the microcontroller or processor 104 to display visual information on a display device, for example, a wearable computing device, for example, a wearable computing device in color and/or gray scale in a plurality of display modes that is substantially similar to the display modes described above with reference to FIGS. 2-7B. The following are examples of display modes that may be provided on LCD display 114 (FIG. 1) to a user of the wearable computing device using MIP pixel 800: 1) reflective color MIP mode (8 color or 64 color); 2) transmissive color MIP mode (8 color or 64 color); 3) hybrid transflective MIP mode (8 color or 64 color); 4) high color depth transmissive mode (262K or 16M color); and 5) hybrid transflective high color depth mode (262K or 16M color).

1) Reflective Color MIP Mode (8 Color or 64 Color):

The LCD display 114 may be configured to display color information to a user outdoors in bright sunlight and color indoors in well-lit conditions with the transmissive sub-pixels being turned OFF and the reflective sub-pixels being turned ON with the MIP driving the reflective sub-pixels. In this mode, reflective color is used to display visual information 8 colors, for example, i-bit on each red, green and blue sub-pixel, or 64 color using reflective color and where a light source, for example, sunlight or indoor light is available to provide reflectivity. As such, the color MIP mode improves on outdoor readability of the prior art by using the reflective MIP to drive the reflective sub-pixels so as to provide good outdoor readability and color in sunlight, good indoor readability under lighted conditions and consume very low power.

2) Transmissive Color MIP Mode (8 Color or 64 Color):

The LCD display 114 may be configured to display visual information to a user in 8 colors, for example, i-bit on each red, green and blue sub-pixel, or 64 color using the transmissive color MIP mode with the reflective sub-pixels being turned OFF and the transmissive sub-pixels being turned ON with the MIPs driving the transmissive sub-pixel electrodes and the backlight unit being used as a light source. The LCD display 114 may use the transmissive color MIP mode to display color information indoors in dim light, used to display color information indoors under normal lighted conditions or used to display color information outdoors in bright sunlight by boosting transmissive color readability, and display black and white, using only the transmissive sub-pixels. The transmissive color MIP mode improves on the prior art by providing very good and/or color contrast from the transmissive color with very low power consumption for indoor environments.

3) Hybrid Transflective MIP Mode (8 Color or 64 Colors):

The LCD display 114 may be configured to display color information to a user in 8 colors or 64 colors using the hybrid transflective MIP mode with the transmissive sub-pixels being turned ON with the backlight unit used as a light source and the reflective sub-pixels also being turned ON. The transmissive and reflective MIPs both drive their respective transmissive and reflective sub-pixel electrodes at the same time to provide 8 colors as well as black and white for indoor and outdoor use. The LCD display 114 may use the hybrid transflective MIP mode in dim outdoor environments and in dim indoor conditions to display visual information in color and black or white to a user and improves on the prior art by providing good color/contrast indoors under normal or dim indoor conditions and 8-colors outdoors under dark or dim-lighted conditions with very low power consumption.

4) High Color Depth Transmissive Mode:

The LCD display 114 may be configured to display color information with higher color depth, for example, a 262K color mode or a 16M color mode with the transmissive sub-pixels being turned ON and the reflective sub-pixels being turned OFF. The backlight unit is used as a light source and a driver IC circuit drives the transmissive sub-pixel electrodes without using the transmissive MIPs (MIPs turned OFF). The LCD display 114 may use the high color depth transmissive mode in indoor environments and outdoors for displaying visual information generally in vibrant color (with a higher color depth) to a user such as, for example, to display visual information indoors in dim light, used to display visual information indoors under normal lighted conditions or used to display visual information outdoors in order to boost reading color information.

5) Hybrid Transflective High Color Depth Mode:

The LCD display 114 may be configured to display visual information in color with higher color depth such as, for example, a 262K color mode or a 16M color mode and in gray scale using the hybrid transflective high color depth mode with both the transmissive sub-pixels and the reflective sub-pixels being turned ON and being driven by one or more driver IC circuits with the MIPs turned OFF. The backlight unit is used as a light source. Using the IC driver for the reflective sub-pixels may also provide gray scale color. The LCD display 114 may use the hybrid transflective high color depth mode in selective indoor and outdoor environments where there is not enough light such as indoors under dim-lighted conditions or outdoors under dim-lighted conditions.

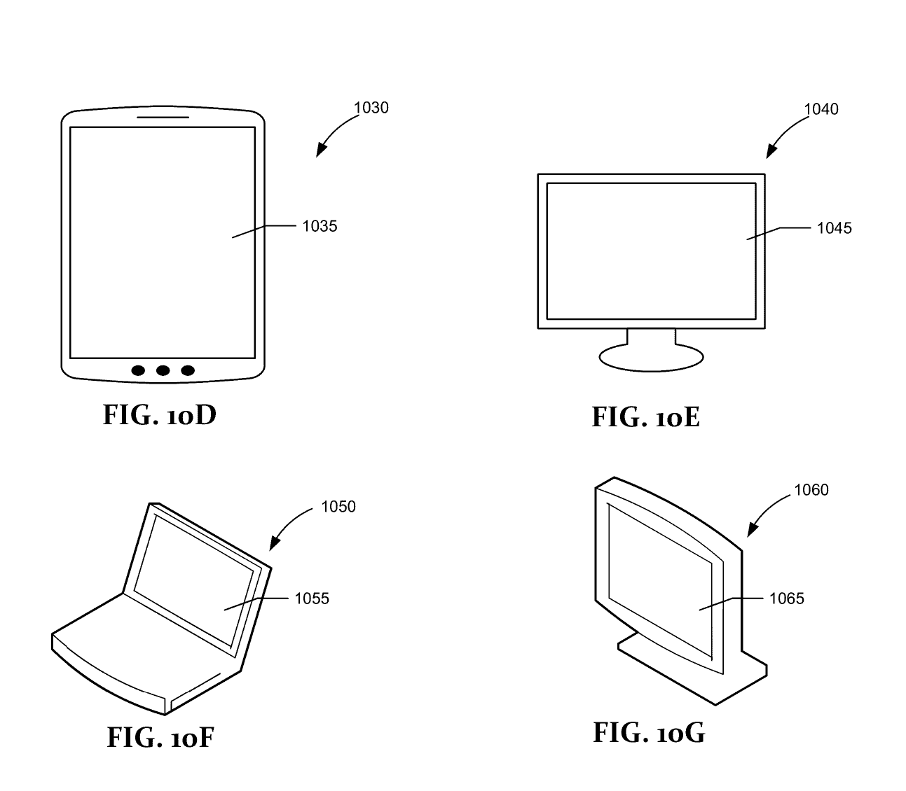

FIGS. 10A-10G illustrate examples of computing devices that may be used with embodiments of the present invention. FIG. 10A is a front view of a smartwatch 1000 that is associated with a wearable computing device having a display 1005 that is used to display visual information to a user according to an embodiment, Display 1005 may be the LCD display 114 of FIG. 1 and may include the transmissive and reflective sub-pixels described in the present invention. FIG. 10B is a front view of a smartphone 1010 with a display 1015 that is used to display visual information to a user according to an embodiment. Display 1015 may be the LCD display 114 of FIG. 1 and may include the transmissive and reflective sub-pixels described in the present invention. FIG. 10C is a front view of a camera 1020 with a display 1025 that is used to display visual information to a user according to an embodiment. Display 1025 may be the LCD display 114 of FIG. 1 and may include the transmissive and reflective sub-pixels described in the present invention. FIG. 10D is a front view of a tablet 1030 with a display 1035 that is used to display visual information to a user according to an embodiment. Display 1035 may be the LCD display 114 of FIG. 1 and may include the transmissive and reflective sub-pixels described in the present invention. FIG. 10E is a front view of a LCD monitor 1040 with a display 1045 that is used to display visual information to a user according to an embodiment. Display 1045 may be the LCD display 114 of FIG. 1 and may include the transmissive and reflective sub-pixels described in the present invention. FIG. 10F is an isometric view of a laptop computer 1050 with a display 1055 that is used to display visual information to a user according to an embodiment. Display 1055 may be the LCD display 114 of FIG. 1 and may include the transmissive and reflective sub-pixels described in the present invention. FIG. 10G is an isometric view of a TV monitor 1060 with a display 1065 that is used to display visual information to a user according to an embodiment. Display 1065 may be the LCD display 114 of FIG. 1 and may include the transmissive and reflective sub-pixels described in the present invention.

As would be understood by those having ordinary skill in the art, the presently disclosed invention may be utilized with other MIP structures and designs, other sub-pixel shapes, other black and white and color sub-pixel arrangements in the full pixel array as is generally known to those skilled in the art. Moreover, while 1-bit MIP sub-pixels are used in the various embodiments, those of skill in the art would recognize that higher-bit sub-pixels may also be used to implement the disclosed invention.

It will also be understood that the above description is intended to be illustrative, and not restrictive. For example, the above-described embodiments may be used in combination with each other and features of one embodiment may be utilized with other embodiments. Many other embodiments will be apparent to those of ordinary skill in the art upon reviewing the above description. For example, pixel structure with the transmissive and reflective sub-pixels may be implemented in displays associated with portable computing devices, smart phones, computers, televisions or other similar devices. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.”

1. A liquid crystal display (LCD), comprising:
a plurality of pixels arranged in a matrix, wherein each pixel of the plurality of pixels further comprises:
a plurality of scan lines disposed along a first direction on a glass substrate;
a plurality of signal lines disposed along a second direction on the glass substrate;
a transmissive sub-pixel zone comprising a plurality of transmissive sub-pixels and a reflective sub-pixel zone comprising a plurality of reflective sub-pixels;
a transmissive sub-pixel electrode disposed on the glass substrate within a respective transmissive sub-pixel;
a reflective sub-pixel electrode disposed over the glass substrate within a reflective sub-pixel;
a first memory-in-pixel (MIP) including a plurality of switch devices formed on the glass substrate and contained within the reflective sub-pixel for controlling the transmissive sub-pixel; and
a second MIP including a plurality of switch devices formed on the glass substrate and contained within the reflective sub-pixel for controlling the reflective sub-pixel,
wherein each of the transmissive sub-pixels and each of the reflective sub-pixels have geographic boundaries defined by the scan lines and the signal lines,
wherein the first MIP is contained under the reflective sub-pixel electrode with a first switch device being associated with the transmissive sub-pixel, and
wherein the second MIP is contained under the reflective sub-pixel electrode with a second switch device being associated with the reflective sub-pixel.

2. (canceled)

3. The LCD of claim 1, wherein the plurality of transmissive sub-pixels are connected to a scan line through a respective switch device.

4. The LCD of claim 1, wherein the plurality of reflective sub-pixels are connected to a second scan line through a respective switch device.

5. (canceled)

6. The LCD of claim 1, wherein the pixel further comprises a common electrode that extends from the transmissive sub-pixel zone to the reflective sub-pixel zone.

7. The LCD of claim 1, wherein the pixel further comprises a second glass substrate that is disposed over the common electrode and that extends from the transmissive sub-pixel zone to the reflective sub-pixel zone.

8. The LCD of claim 7, wherein the pixel further comprises a color filter that is disposed over the glass substrate and covers the transmissive sub-pixel electrode and the reflective sub-pixel electrode.

9. The LCD of claim 7, wherein the pixel further comprises a color filter that is disposed over the glass substrate and only covers the transmissive sub-pixel electrode.

10. The LCD of claim 1, wherein MIPs are configured to drive only the reflective sub-pixels in a black and white MIP mode using MIPs for the reflective sub-pixels and ambient light as a light source.

11. The LCD of claim 1, wherein MIPs are configured to drive only the transmissive sub-pixels in a transmissive color MIP mode using MIPs for the transmissive sub-pixels and a backlight as a light source.

12. The LCD of claim 1, wherein MIPs are configured to drive both the transmissive sub-pixels and the reflective sub-pixels in a hybrid transflective color MIP mode using MIPs for the transmissive and reflective sub-pixels and a backlight as a light source.

13. The LCD of claim 1, wherein one or more driver circuits are configured to drive only the transmissive sub-pixels in a high color depth transmissive mode using a backlight as a light source and without using MIPs for the transmissive sub-pixels.

14. The LCD of claim 1, wherein one or more driver circuits are configured to drive both the transmissive sub-pixels and the reflective sub-pixels in a hybrid transflective high color depth mode using a backlight as a light source and without using MIPs for the transmissive or the reflective sub-pixels.

15. A pixel structure comprising:
a plurality of scan lines disposed along a first direction on a glass substrate;
a plurality of signal lines disposed along a second direction on the glass substrate;
a transmissive sub-pixel zone comprising a plurality of transmissive sub-pixels and a reflective sub-pixel zone comprising a plurality of reflective sub-pixels;
a transmissive sub-pixel electrode disposed on the glass substrate within a respective transmissive sub-pixel;
a reflective sub-pixel electrode disposed over the glass substrate within a reflective sub-pixel; and
a first memory-in-pixel (MIP) including a plurality of switch devices formed on the glass substrate and contained within the reflective sub-pixel for controlling the transmissive sub-pixel,
wherein each of the transmissive sub-pixels and each of the reflective sub-pixels have geographic boundaries defined by the scan lines and the signal lines, and
wherein the first MIP is contained under the reflective sub-pixel electrode with a first switch device being associated with the transmissive sub-pixel.

16. (canceled)

17. The pixel structure of claim 15, wherein the plurality of transmissive sub-pixels are connected to a scan line through a respective switch device.

18. The pixel structure of claim 15, wherein the plurality of reflective sub-pixels are connected to a second scan line through a respective switch device for the at least one MIP.

19. (canceled)

20. The pixel structure of claim 15, further comprising a common electrode that extends from the transmissive sub-pixel zone to the reflective sub-pixel zone.

21. The pixel structure of claim 15, further comprising a second glass substrate that is disposed over the common electrode and that extends from the transmissive sub-pixel zone to the reflective sub-pixel zone.

22. The pixel structure of claim 15, further comprising a color filter that is disposed over the glass substrate and only covers the transmissive sub-pixel electrode.

23. The pixel structure of claim 15, further comprising a first color filter and a second color filter that are disposed over the glass substrate, wherein the first color filter covers the transmissive sub-pixel electrode and the second color filter covers the reflective sub-pixel electrode.

24. The pixel structure of claim 15, wherein MIPs are configured to drive only the reflective sub-pixels in a black and white MIP mode using ambient light as a light source.

25. The pixel structure of claim 15, wherein MIPs are configured to drive only the transmissive sub-pixels in a transmissive color MIP mode using a backlight as a light source.

26. The pixel structure of claim 15, wherein MIPs are configured to drive both the transmissive sub-pixels and the reflective sub-pixels in a hybrid transflective color MIP mode using a backlight as a light source.

27. The pixel structure of claim 15, wherein one or more driver circuits are configured to drive only the transmissive sub-pixels in a high color depth transmissive mode using a backlight as a light source and without using MIPs for the transmissive sub-pixels.

28. The pixel structure of claim 15, wherein one or more driver circuits are configured to drive both the transmissive sub-pixels and the reflective sub-pixels in a hybrid transflective high color depth mode using a backlight as a light source and without using MIPs for the transmissive sub-pixels transmissive or the reflective sub-pixels.

29. The pixel structure of claim 15, further comprising a second MIP including a plurality of switch devices formed on the glass substrate and contained within the reflective sub-pixel for controlling the reflective sub-pixel.

30. The pixel structure of claim 29, wherein the second MIP is contained under the reflective sub-pixel electrode with a second switch device being associated with the reflective sub-pixel.
